(19) United States
(12) Patent Application Publication
(10) Pub. No.: US 2003/0207584 A1
(43) Pub. Date: Nov. 6, 2003

(54) Patterning tighter and looser pitch geometries

(76) Inventors: Swaminathan Sivakumar, Portland, OR (US); Mark Bohr, Aloha, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/136,514

(22) Filed: May 1, 2002

(51) Int. Cl. H01L 21/302; H01L 21/461

(52) U.S. Cl. 438/717; 438/736

(57) ABSTRACT

Looser and tighter pitch geometries in semiconductor layouts may be fractured into separate groups and defined separately on at least two separate photomasks. Thereafter, the looser pitch geometries may be exposed using a first mask and the tighter pitch geometries may be exposed using a second mask. The conditions of exposure may be optimized for the different geometries. As a result, the customized exposures for each type of geometry may be optimized without some of the compromises conventionally required.

### BACKGROUND

This invention relates generally to the fabrication of semiconductor integrated circuits.

In the manufacture of semiconductor integrated circuits, patterned elements are formed on the surface of a semiconductor substrate. Generally, a photoresist material is deposited or otherwise formed on the semiconductor substrate. That material is then selectively exposed to light. The regions that are exposed to light react differently to the subsequent development step than regions that are not exposed. As a result, patterns may be transferred from the mask repeatedly to the photoresist and subsequently through etching to the semiconductor substrates to produce a number of integrated circuits.

A typical design layout for an integrated circuit includes patterns having varying pitches, ranging from the tightest pitch allowed by the design rules for the semiconductor process to relative loose or isolated pitches. The pitches are a measure of how complicated, detailed or closely spaced are the structures that are being defined on the semiconductor substrate.

Patterning a nested or tight pitch geometry requires exposure conditions that are very different from those used to print loose or isolated geometries. It is relatively difficult to find patterning conditions that perform reasonably well for both tight pitch and isolated structures. Such an operating point invariably makes significant compromises at both ends of the distribution, leading to a process with reduced margin overall for all structures.

Currently, designs that involve both loose and tight pitch geometries are handled by a single pass masking process. The tight pitch and loose pitch geometries are formed in the same mask, and the mask is exposed under conditions that are compromised between those that are ideal for the looser pitch and tighter pitch geometries. This results in degraded margin for both geometries.

Therefore, there is need for better ways to handle designs that involve both loose and tight pitch geometries.

### BRIEF DESCRIPTION OF THE DRAWINGS

FIG. 1 is a partial, top plan view of a mask for tight pitch geometries in accordance with one embodiment of the present invention;

FIG. 2 is a partial, cross-sectional view showing the mask in position over a substrate in accordance with one embodiment of the present invention;

FIG. 3 is a partial, top plan view of a semiconductor substrate that has been patterned using the mask shown in FIG. 1 in accordance with one embodiment of the present invention;

FIG. 4 is a partial, top plan view of a second mask in accordance with one embodiment of the present invention;

FIG. 5 is a partial, cross-sectional view showing a mask in position over a semiconductor substrate in accordance with one embodiment of the present invention; and

FIG. 6 is a partial, top plan view of a patterned semiconductor substrate in accordance with one embodiment of the present invention.

### DETAILED DESCRIPTION

In accordance with one embodiment of the present invention, shown in the figures, a design layout that includes tight and loose pitch geometries may be split into two separate masks. A first mask includes the tight pitch patterns and the second mask includes the loose pitch patterns. A dual exposure technique is utilized to pattern tight and loose pitch structures on the same photomasking layer.

In the first pass exposure, in one embodiment, tight geometries are printed using exposure conditions suited for tight pitches but not for looser or isolated structures. In the second pass exposure, the remaining patterns at looser pitches are printed with exposure settings optimized for looser pitches, but incapable of printing tighter pitches. This enables the use of customized exposures for tight and loose pitch geometries instead of using a compromise with degraded overall performance.

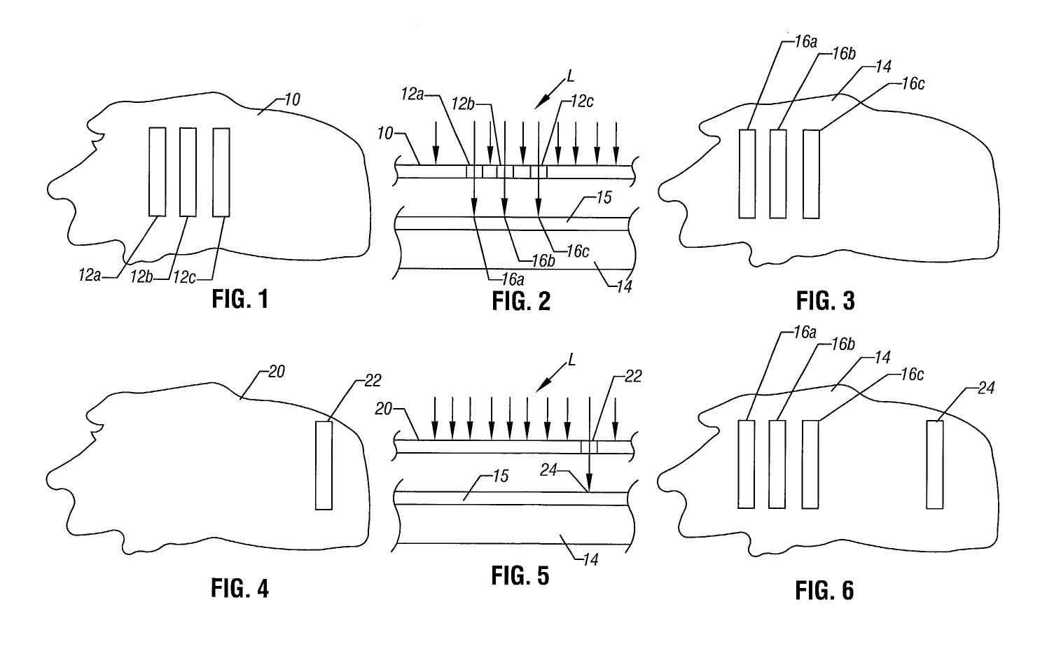

Referring to FIG. 1, the first pass mask 10 includes openings 12a, 12b, and 12c which may be characterized as a relatively tight pitch geometry since three structures are relatively closely positioned together.

As shown in FIG. 2, the mask 10 is positioned over a semiconductor substrate and exposed to a light or other beam L. The exposure conditions may be optimized for the tight pitch geometry. The beam L passes through the openings 12 in the first pass mask 10 exposing the semiconductor substrate 14 as indicated at 16a, 16b, and 16c. As a result, a photomasking layer 15 on the substrate 14 is selectively exposed based on the positions of the openings 12 in the first pass mask 10. The sensitivity of the exposed regions to a subsequent etching step is thereby altered.

As shown in FIG. 3, patterned structures 16a, 16b, and 16c may be defined on the semiconductor substrate 14. The regions 16 may then be etched or not etched at a subsequent stage.

Next, the looser pitch geometries may be defined. For this purpose, a loose pitch mask 20 may include an opening 22 to define a looser pitch geometry as shown in FIG. 4. In each case, the masks 10 and 20 are shown partially because each mask 10 or 20 may include a large number of elements. Ideally, all of the tighter pitch elements are defined on the first pass mask 10 and all of the looser pitch geometries are defined on the second pass mask 20 in some embodiments.

The mask 20 is then used to expose the photomasking layer 15 on the semiconductor substrate 14 as shown in FIG. 5. Again, the opening 22 in the mask 20 allows the beam L to pass through, exposing the layer 15. In this case, the exposure conditions may be optimized for printing looser pitch geometries. The exposure pattern shown in FIG. 5 may result in a region 24 being exposed as a result of the opening 22.

The structure shown in FIG. 5 may then be exposed to a patterning or etching step, to either selectively remove or retain the regions 16 and 24 that were exposed to the beam L by the openings 12 or 22 in the masks 10 and 20. As shown in FIG. 16, the regions 16 and 24 may be removed from the layer 15 in one embodiment or in another embodiment the surrounding portions of the layer 15 may be removed.

While in the embodiment illustrated, the tighter pitch geometries are exposed first followed by the exposure of the looser pitch geometries, in other embodiments the looser pitch geometries may be exposed first and the tighter pitch geometries exposed second. In any case, by providing at least two different exposure steps, using at least two different masks under conditions optimized for looser or tighter pitch geometries, the margin of the overall layout may be improved. This is because the printing of the tighter pitch geometries may be optimized for those geometries, while the looser pitch geometries may be printed using techniques optimized for their characteristics.

The wafers may be exposed with the two masks one after the other in a single pass through the exposure tool and developed. The exposure used to print the tight pitch features may use strong resolution enhancement techniques, such as Attenuated Phase Shifting Mask (APSM) or strong oblique illumination that significantly improves tight pitch resolution and degrees of freedom. The exposure to print loose pitch or isolated features can use conventional illumination to extract as much performance as possible for these structures.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
exposing a tighter pitch geometry pattern on a semiconductor surface using a first mask; and
exposing a looser pitch geometry pattern on the semiconductor substrate using a second mask.

2. The method of claim 1 including using different exposure conditions with said first and second masks.

3. The method of claim 1 including exposing said tighter pitch geometry pattern before exposing said looser pitch geometry pattern.

4. The method of claim 1 including developing said patterns after exposing said patterns using said first and second masks.

5. A method comprising:
exposing a first pattern on a semiconductor structure; and
exposing a second pattern on the semiconductor structure using different exposure conditions than were used with said first pattern.

6. The method of claim 5 wherein exposing a first pattern on a semiconductor structure includes exposing a first pattern made up of tighter pitch geometry elements.

7. The method of claim 6 wherein exposing a second pattern includes exposing looser pitch patterns on the semiconductor structure.

8. The method of claim 5 including using different masks to expose said first and second patterns.

9. The method of claim 8 including developing said patterns after exposing said patterns using said first and second masks.

10. The method of claim 5 including exposing a tighter pitch geometry pattern before exposing a looser pitch geometry pattern.

11. A method comprising:
dividing a layout into tighter and looser pitch geometry elements; and
forming a first mask including said tighter pitch geometry elements and a second mask including said looser pitch geometry elements.

12. The method of claim 11 including exposing a substrate using said first and second masks.

13. The method of claim 12 including using different exposure conditions with said first and second masks.

14. The method of claim 13 including exposing said tighter pitch geometry elements before exposing said looser pitch geometry elements to form patterns on a semiconductor structure.

15. The method of claim 14 including developing said patterns after exposing said patterns using said first and second masks.

16. A photolithography mask set comprising:
a first mask including tighter pitch geometry patterns to be exposed on a semiconductor structure; and
a second mask including looser pitch geometry patterns to be exposed on the same semiconductor structure.

17. The mask set of claim 16 wherein said tighter and looser pitch geometry patterns are physically offset from one another.
